(19) United States
(12) Patent Application Publication
(10) Pub. No.: US 2007/0148862 A1
(43) Pub. Date: Jun. 28, 2007

(54) Phase-change memory layer and method of manufacturing the same and phase-change memory cell

(76) Inventors: Yi-Chan Chen, Hsinchu (TW); Hong-Hui Hsu, Hsinchu (TW); Chien-Min Lee, Hsinchu (TW); Yen Chuo, Hsinchu (TW); Te-Sheng Chao, Hsinchu (TW); Wen-Han Wang, Hsinchu (TW); Wei-Su Chen, Hsinchu (TW); Min-Hung Lee, Hsinchu (TW)

Correspondence Address: RABIN & Berdo, PC, 1101 14TH STREET, NW, SUITE 500, WASHINGTON, DC, 20005, US

(21) Appl. No.: 11/437,661

(22) Filed: May 22, 2006

(30) Foreign Application Priority Data
Dec. 23, 2005 (TW) 094146237

(51) Int. Cl. H01L 21/336

(52) U.S. Cl. 438/257

(57) ABSTRACT

A phase-change memory layer and method for manufacturing the same and a phase-change memory cell are provided. The phase-change memory layer is crystallized by adding one or more heterogeneous crystals that do not react with phase-change materials as the crystal nucleus, so as to reduce the time for transforming to the crystalline state from the amorphous state.

### CROSS-REFERENCE TO RELATED APPLICATIONS

This non-provisional application claims priority under 35 U.S.C. § 119(a) on Patent Application No(s). 094146237 filed in Taiwan, R.O.C. on Dec. 23, 2005, the entire contents of which are hereby incorporated by reference.

### BACKGROUND OF THE INVENTION

1. Field of Invention

The present invention relates to a phase-change memory layer, and more particularly to the phase-change memory layer with one or more heterogeneous micro-crystals that do not react with the phase-change materials and the properties of which do not change with temperature changes as the crystal nucleus for crystallizing the phase change layer and the method for manufacturing the same and a phase-change memory cell.

2. Related Art

Phase-change memory uses a phase-change memory layer transforming between a crystalline state and an amorphous state, thus achieving the purpose of writing and resetting. In the amorphous state (with an irregular atomic structure), the phase-change memory layer presents a high resistance value, while in the crystalline state (with a regular atomic structure), the phase-change memory layer presents a low resistance value. Therefore, the phase-change memory layer functions as a non-volatile programmable resistor, which can reversibly transform between the high resistance and low resistance value alternately.

The phase-change memory layer is formed by a chalcogenide material with the function of transforming between amorphous and crystalline phases. Two memory materials Tc₈₅Ge₁₅ and Te₈₁Ge₁₅S₂Sb₂ are disclosed in U.S. Pat. No. 3,530,441, S. R. Ovsinsky, in which a reversible phase transformation can be performed when the two materials are radiated with a high energy laser. Then, the chalcogenide has become a research focus. Later, all the successively developed phase-change memory materials belong to chalcogenide materials, such as GeTe, InSe, InSeTl, GeTeSb, GeTeSnAu, and the like. The GeSbTe species, developed by the Matsushita Corporation of Japan, attracts the most attention.

The Matsushita Corporation of Japan has published several US patents on the GeSbTe species. For example, U.S. Pat. No. 5,233,599, filed on Aug. 3, 1993, discloses a kind of GeSbTe which is composed by a certain point G of Ge₁₂Sb₃₉Te₄₉ on the line of GeSb2Te4 and Sb in a ternary phase diagram. The best memory property (a low jitter value) can be achieved within the composition scope near the point G (7 to 17 atomic weight % (at. %) Ge, 34 to 44 at. % Sb, 44 to 54 at. % Te).

Further, U.S. Pat. No. 5,278,011, filed on Jan. 11^{th}, 1994, discloses that in the composition scope near the pseudobinary alloy line of GeTe—Sb₂Te₃ and GeTe—BiTe₃, a part of Te is replaced by Se, or an appropriate amount of the element Bi is added, thus keeping a rapid crystallization speed while enhancing the memory sensitivity.

Currently, the operation speed of the phase-change memory depends on the transformation speed of the phase-change memory layer. But, the phase-change memory layer is usually made of Ag—In—Te—Sb that is a material for the phase-change layer. However, since the crystallization temperature is relatively high, the time for transforming the phase-change memory layer from the amorphous state structure to the crystalline state structure is also relatively long. And when resetting, a relative long time period is required for completely transforming the phase change layer from the amorphous state structure to the crystalline state structure, which is limited by the time for the nucleation and crystal growth during the crystallization of the phase-change materials.

### SUMMARY OF THE INVENTION

The present invention provides a phase-change memory layer and the method of manufacturing the same and a phase-change memory cell, wherein the heterogeneous micro-crystals are fabricated into the phase-change material layer, as the crystal nucleus for the crystallization and growth of the phase-change memory cell, so as to reduce the time for transforming from the amorphous state into the crystalline state, thereby enhancing the operation speed of the phase-change memory.

A method for manufacturing the phase-change memory layer is disclosed in the present invention. The phase-change memory cell can be transformed between the amorphous state and the crystalline state. The method comprises first forming a stacked layer by a plurality of thin film layers of the heterogeneous passivation materials and a plurality of phase-change material layers alternated, and transforming the plurality of thin film layers of the heterogeneous passivation material to a plurality of crystals, wherein the crystals are used as the nucleus positions when transforming between the amorphous state and the crystalline state.

The material of the film layer of the heterogeneous passivation material is a material that cannot react with the phase-change material of the phase-change material layer, and the properties of which do not change with the temperature changes. And the preferred materials include oxides, nitrides, and carbides.

Furthermore, the process for transforming the heterogeneous passivation material film layers to a plurality of crystals includes one or more of an annealing process, a thin film co-sputtering process, a plasma implantation process, and an ion implantation process.

Additionally, the phase-change memory layer formed through the above processes disclosed in the present invention includes a phase-change material layer. The phase-change material layer includes several crystals, and is formed by forming a stacked layer by several phase-change material layers and several heterogeneous passivation material film layers alternated, and transforming the heterogeneous passivation material film layer within the stacked layer, wherein the crystals are used as the nucleus position during the state transformation between the amorphous state and the crystalline state.

The material of the heterogeneous passivation material film layer includes SiO_{X}, SiN_{X}, TiO_{X}, TaO_{X}, Al₂O₃, or CN_{X}, or the like. And the phase-change material of the phase-change material layer can be selected from among chalcogenide materials.

The phase-change memory cell disclosed in the present invention includes a first dielectric layer, a first electrode (also referred to as a heating electrode), a phase-change material layer, a second dielectric layer, and a second electrode. The first electrode is located within the first dielectric layer. The phase-change material layer is located on the first electrode and has several crystals, wherein after several phase-change material layers and several heterogeneous passivation material film layers are alternated to form a stacked layer, each of the crystals is formed through the state transformation of each heterogeneous passivation material film layer within the stacked layer. And the crystals are used as the nucleus position when transforming between the amorphous state and the crystalline state.

The second dielectric layer is located on the phase-change material layer, and the second electrode is located within the second dielectric layer.

The phase-change material layer in the phase-change memory cell is the above phase-change material layer disclosed in the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given herein below for illustration only, and which thus is not limitative of the present invention, and wherein:

FIGS. 1A and 1B are the phase-change memory layer and the method of manufacturing the same according to the present invention;

FIG. 2 is the nucleus positions for the phase-change reaction provided by the heterogeneous crystals;

FIG. 3 is the tension and stress provided by the heterogeneous crystals; and

FIG. 4 is a phase-change memory cell with the phase-change memory layer of the present invention.

### DETAILED DESCRIPTION OF THE INVENTION

Conventionally, in order to enhance the operation speed of a phase-change memory, the properties of the materials of the phase-change material layer 10, such as doped Sn, Sb, As, Se, S, O, Bi, and other elements, are changed, and thereby the growth mechanism (i.e., the state transformation between the amorphous state and the crystalline state) of the phase-change material layer 10 is changed during the phase-change reaction. However, through this method, when several times of phase-change reactions are carried out, the doped elements will be distributed un-uniformly. Accordingly, the problem of whether the writing and erasing can be repeated arises, and the operation of the phase-change memory requires high power consumption. The material of the phase-change material layer 10 in the present invention is not changed, but one or more kinds of heterogeneous micro-crystals that do not react with the phase-change material layer 10 are fabricated to be the crystal nucleus 40 grown during the crystallization of the phase-change material in the amorphous area, so as to reduce the time required for transforming from the amorphous state into the crystalline state.

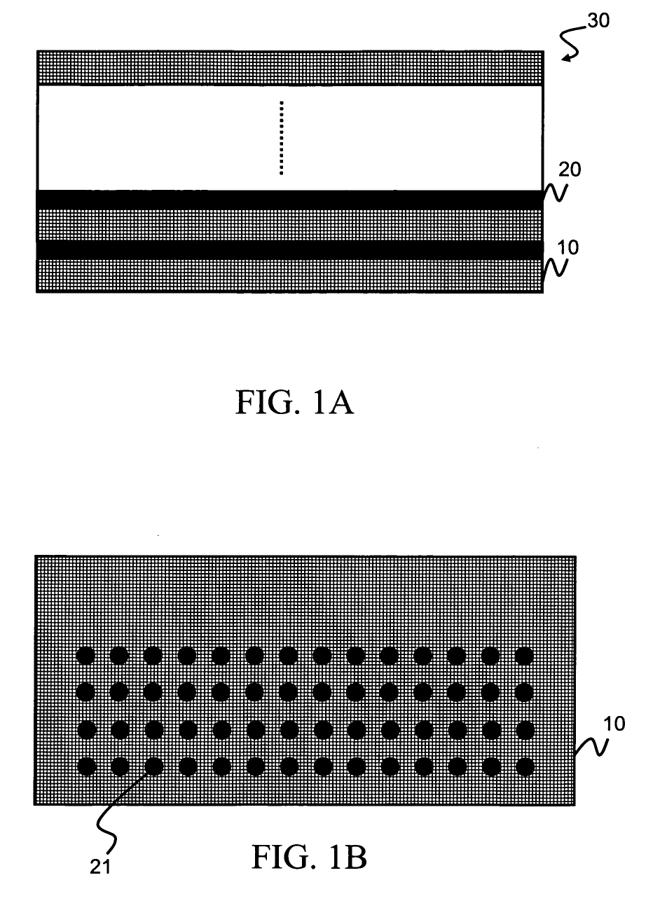

Referring to FIGS. 1A and 1B, the phase-change memory layer and the method of manufacturing the same provided according to the present invention are illustrated. The phase-change memory layer is used for the phase-change reaction, i.e., transforming from the amorphous state into the crystalline state. First, referring to FIG. 1A, through chemical vapor deposition (CVD) or physical vapor deposition (PVD), one or more heterogeneous passivation materials (such as SiO_{X}, SiN_{X}, TiO_{X}, TaO_{X}, Al₂O₃, CN_{X}, and the like) and phase-change materials (such as chalcogenide materials) form a stacked layer 30 with several heterogeneous passivation material film layers 20 and several phase-change material layers 10 alternated.

Herein, in the stacked layer 30 with thin films alternated, the thickness of the heterogeneous passivation material film layer 20 is preferred to be 1 nm to 3 nm, and the stacked layer 30 is formed at the ½ to ⅓ of the phase-change memory layer, close to the heating electrode of the phase-change memory.

Then, the alternated stacked layer 30 go through an annealing process, such that the heterogeneous passivation material film layer 20 within the stacked layer 30 is transformed into crystals 21, that is, the difference between the thermal expansion coefficients of the heterogeneous passivation materials and the phase-change materials are used to transform the heterogeneous passivation material film layer 20 into ball-shaped, silk-shaped, or irregular-shaped crystals 21 within the alternated stacked layer 30. These crystals 21 must be uniformly distributed within the phase-change material layer 10, as shown in FIG. 1B.

The process for transforming the heterogeneous passivation material film layer 20 into several crystals 21 within the stacked layer 30 includes one or more of a co-sputtering process, a plasma implantation process, and an ion implantation process.

Furthermore, FIG. 1B shows a phase-change memory layer according to the present invention. The phase-change memory layer includes a phase-change material layer 10. Several phase-change material layers 10 and several heterogeneous passivation material film layers 20 are alternated to form a stacked layer 30, and then the several heterogeneous passivation material film layers 20 are transformed within the stacked layer 30, so as to form several crystals 21. The crystals 21 are used as the positions of the crystal nucleuses 40 during the state transformation between the amorphous state and the crystalline state.

In addition, the material of the above heterogeneous passivation material film layer 20 can be selected from among materials that do not react with the material of the phase-change material layer 10, and the properties of which do not change as the temperature changes. Preferred material includes oxides, carbides, and nitrides. Therefore, when the phase-change reaction occurs to the phase-change memory layer, the micro heterogeneous crystals 21 do not chemically react with the phase-change materials, such that the un-uniform distribution of the doped elements in the conventional art can be avoided.

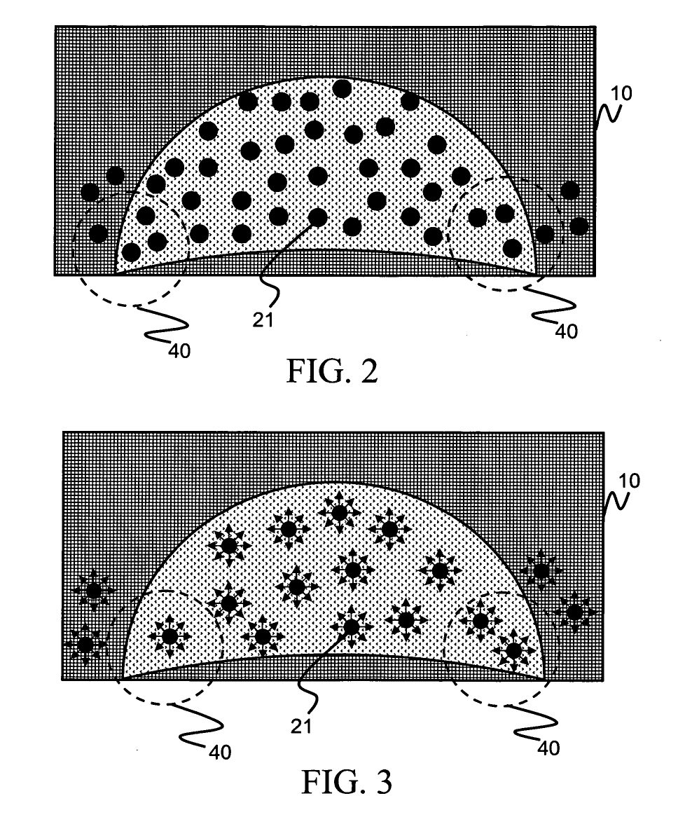

In other words, during the phase-change reaction (i.e., transforming from the amorphous state into the crystalline state), the uniformly distributed micro heterogeneous crystals 21 provides the positions of the crystal nucleuses 40 during the crystallization of the phase-change material in the amorphous area, as shown in FIG. 2, so as to reduce the time for nucleation of the crystal nucleus 40 during the phase-change reaction to achieve a rapid phase transformation, and reduce the power consumption of the phase-change reaction.

Further, the phase-change memory provides repeatedly high-speed reading and writing. If the time for the phase-change reaction of the phase-change memory layer is reduced through the above technique of the doped elements, after several times of phase-change reactions, the elements doped in the phase-change memory layer are distributed un-uniformly, such that the phase-change memory layer cannot accurately return the amorphous state from the crystalline state. And the problem whether it can be repeatedly read and erased occurs.

However, through the phase-change memory layer provided in the present invention, after multiple phase-change reactions, the micro heterogeneous crystals 21 still can be used to provide tension and stress, such that the phase-change memory layer can be accurately returned to the amorphous state from the crystalline state, as shown in FIG. 3.

As for the phase-change memory layer and the method for manufacturing the same according to the present invention, the heterogeneous passivation material film layers 20 are transformed to form several crystals 21. The crystals 21 are used as the positions of the crystal nucleuses 40 during the state transformation between the amorphous state and the crystalline state, such that the phase-change memory layer provides tension and stress through the micro heterogeneous crystals 21. Thus, during the crystallization of the phase-change material, the time for nucleation and growth of the crystal nucleus 40 is reduced; thereby the operation speed of the phase-change memory is enhanced.

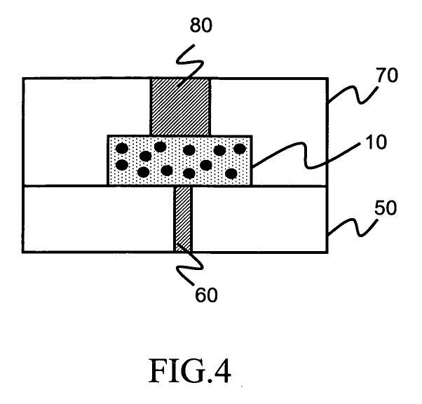

Furthermore, referring to FIG. 4, the phase-change memory layer provided in the present invention is applied to the phase-change memory cell. The phase-change memory cell includes a first dielectric layer 50, a first electrode 60 (also referred as a heating electrode), a phase-change material layer 10, a second dielectric layer 70, and a second electrode 80.

The first electrode 60 is located within the first dielectric layer 50. The phase-change material layer 10 is located on the first electrode 60 and has several crystals 21. After several phase-change material layers 10 and several heterogeneous passivation material film layers 20 are alternated to form a stacked layer 30, each crystal 21 is formed through the state transformation of each heterogeneous passivation material film layer 20 within the stacked layer 30, and the crystals 21 act as the positions of the crystal nucleuses 40 during the state transformation between the amorphous state and the crystalline state.

The state transformation of the heterogeneous passivation material film layer 20 within the stacked layer 30 also can be achieved through one or more of the thin film co-sputtering process, the plasma implantation process, and the ion implantation process. The materials of the heterogeneous passivation material film layer 20 can be selected from among nitrides, oxides, and carbides, and the nitrides, oxides, and carbides further include SiO_{X}, SiN_{X}, TiO_{X}, TaO_{X}, Al₂O₃, or CN_{X}, and the like.

Additionally, the second dielectric layer is located on the phase-change material layer 10, and the second electrode 80 is located within the second dielectric layer 70.

The material of the first electrode 60 (or referred as a heating electrode) can be a conductive material with high resistance, such as Ti, Ta, TiN, TaN, TiAlN_{X}, TiCN_{X}, TaW, TiW, TaO_{X}, poly-Si, TaSiO, C, SiC, GeN, and the like. The materials of the first dielectric layer 50 and the second dielectric layer 70 can be dielectric materials, such as SiO₂, Si₃N₄, and the like. The materials of the second electrode 80 can be conductive materials with high conductivity, such as Al, W, Mo, Ti, Cu, and the like.

Furthermore, the phase-change memory cell can be achieved thorough the conventional complementary metal-oxide semiconductor (CMOS) process.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

What is claimed is:

1. A method for manufacturing a phase-change memory layer, wherein the phase-change memory layer provides a state transformation between an amorphous state and a crystalline state, the method comprising:
forming a stacked layer by a plurality of heterogeneous passivation material film layers and a plurality of phase-change material layers alternated; and
transforming the heterogeneous passivation material film layers to a plurality of crystals as a nucleus position during the state transformation between the amorphous state and the crystalline state.

2. The method for manufacturing the phase-change memory layer according to claim 1, wherein in the step of transforming the heterogeneous passivation material film layers to a plurality of crystals, the materials of the heterogeneous passivation material film layer is selected from the group consisting of nitride, oxide, and carbide, and the nitride, oxide, and carbide group includes SiO_{X}, SiN_{X}, TiO_{X}, TaO_{X}, Al₂O₃, and CN_{X}.

3. The method for manufacturing the phase-change memory layer according to claim 1, wherein the process for forming a stacked layer includes a chemical vapor deposition (CVD) process.

4. The method for manufacturing the phase-change memory layer according to claim 1, wherein the process for forming a stacked layer includes a physical vapor deposition (PVD) process.

5. The method for manufacturing the phase-change memory layer according to claim 1, wherein the process for transforming the heterogeneous passivation material film layer to a plurality of crystals is selected from the group consisting of an annealing process, a thin film co-sputtering process, a plasma implantation process, and an ion implantation process.

6. A phase-change memory layer, transforming between an amorphous state and a crystalline state, comprising:
a phase-change material layer, having a plurality of crystals, wherein after a plurality of phase-change material layers and a plurality of heterogeneous passivation material film layers are alternated with each other to form a stacked layer, the plurality of crystals are formed by transforming the heterogeneous passivation material film layers in the stacked layer, and the crystals are used as a nucleus position during the state transformation between the amorphous state and the crystalline state.

7. The phase-change memory layer according to claim 6, wherein the material of the heterogeneous passivation material film layer is selected from the group consisting of nitride, oxide, and carbide, and the nitride, the oxide, and the carbide group includes SiO_{X}, SiN_{X}, TiO_{X}, TaO_{X}, Al₂O₃, and CN_{X}.

8. The phase-change memory layer according to claim 6, wherein the process for transforming the heterogeneous passivation material film layers to a plurality of crystals is selected from the group consisting of an annealing process, a thin film co-sputtering process, a plasma implantation process, and an ion implantation process.

9. The phase-change memory layer according to claim 6, wherein the process for forming the stacked layer includes a CVD process.

10. The phase-change memory layer according to claim 6, wherein the process for forming the stacked layer includes a physical PVD process.

11. A phase-change memory cell, comprising:
a first dielectric layer;
a first electrode, located within the first dielectric layer;
a phase-change material layer, located on the first electrode and having a plurality of crystals, wherein after a plurality of phase-change material layers and a plurality of heterogeneous passivation material film layers are alternated with each other to form a stacked layer, the crystals are formed by transforming the heterogeneous passivation material film layers in the stacked layer, and the crystals are used as a nucleus position during the state transformation between the amorphous state and the crystalline state;
a second dielectric layer, located on the phase-change material; and
a second electrode, located within the second dielectric layer.

12. The phase-change memory cell according to claim 11, wherein the material of the heterogeneous passivation material film layer is selected from the group consisting of nitride, oxide, and carbide, and the nitride, the oxide, and the carbide group includes SiO_{X}, SiN_{X}, TiO_{X}, TaO_{X}, Al₂O₃, and CN_{X}.

13. The phase-change memory cell according to claim 11, wherein the process for transforming the heterogeneous passivation material film layers to a plurality of crystals is selected from the group consisting of an annealing process, a thin film co-sputtering process, a plasma implantation process, and an ion implantation process.

14. The phase-change memory cell according to claim 11, wherein the process for forming the stacked layer includes a CVD process.

15. The phase-change memory cell according to claim 11, wherein the process for forming the stacked layer includes a PVD process.
